(19) United States
(12) Patent Application Publication
(10) Pub. No.: US 2008/0037607 A1
(43) Pub. Date: Feb. 14, 2008

(54) Semiconductor laser diode with a ridge structure buried by a current blocking layer made of un-doped semiconductor grown at a low temperature and a method for producing the same

(76) Inventor: Jun-ichi Hashimoto, Yokohama-shi (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 11/889,461

(22) Filed: Aug. 13, 2007

(30) Foreign Application Priority Data
Aug. 14, 2006 (JP) 2006-221213

(51) Int. Cl. H01S 5/026; H01L 33/00

(52) U.S. Cl. 372/45.01; 438/31; 257/E33.069

(57) ABSTRACT

The present invention provides a laser diode with a current blocking layer without a pn-junction. The laser diode includes a lower cladding layer, an active region and an upper cladding layer on the GaAs substrate in this order. The active region includes first and second regions. The upper cladding layer, which includes a ridge structure, locates on the first region, while, the current blocking region is on the second region of the active region so as to sandwich the ridge structure. The current blocking layer of the invention is made of one of un-doped GaInP and un-doped AlGaInP grown at a relatively low temperature and shows high resistance greater than 10⁵ Ω·cm.

### CROSS REFERENCE TO RELATED APPLICATIONS

This application closely relates to the application by the same inventor and the same assignee, titled by “Semiconductor laser diode with a mesa stripe buried by a current blocking layer made of un-doped semiconductor grown at a low temperature and a method for producing the same”, which is incorporated herein by reference.

### BACKGROUND OF THE INVENTION

1. Field of the Invention

The present invention related to a semiconductor optical device, in particular, the invention relates to a semiconductor laser diode with a ridge waveguide structure.

2. Related Prior Art

The Japanese Journal of Applied Physics, volume 38 (1999), pages from 5888 to 5897, has disclosed a semiconductor laser diode of a type, what is called, the buried-ridge waveguide structure. The laser diode disclosed therein has a double etch-stopping layer (DES layer) made of AlGaAs/InGaP/GaAs. That is, the buried-ridge waveguide region is buried by the current blocking layer that provides a function to confine the current within the ridge waveguide region. Although the current blocking layer disclosed therein may be made of dielectric material, such material generally shows poor thermal conductivity compared to metals or to semiconductors. Moreover, the dielectric material generally has the thermal expansion co-efficient quite different from that of the semiconductor applied in the device. Thus, the current blocking layer made of dielectric material may cause unavoidable stress to the ridge waveguide structure, which may degrade the crystal quality of the grown layer and makes it hard to secure the reliability of the device. Therefore, it is preferable for the current blocking layer to be made of semiconductor material that relaxes the difference in the thermal expansion co-efficient and improves the thermal conductivity compared to those made of dielectric material.

For instance, when the buried ridge structure is formed in the p-type cladding layer, a planar structure of the p-type cladding layer is firstly formed on the active region, the p-type ridge structure for the p-type cladding layer is secondly processed on this planar region, and finally an n-type current blocking layer may be formed on the planar region so as to bury the p-type ridge structure. Thus, these layer arrangements may effectively confine the current into the ridge waveguide structure. The n-type current blocking layer inherently forms a pn-junction with the p-type planar region. This pn-junction is reversely biased when the device normally operates, so, the reversely biased pn-junction may prevent the carriers from flowing therethrough and confine the carriers into the ridge structure.

Thus, a conventional ridge waveguide structure is inevitable to provide the p-type planar region between the n-type current blocking layer and the active region to confine the current in the ridge structure. However, this arrangement to form the reversely biased pn-junction for the current blocking function is unavoidable to increase the parasitic capacitance due to the carriers accumulated in the pn-junction. Accordingly, the laser diode with the current blocking function by the reversely biased pn-junction is unsuitable for the high speed application.

The present invention is to solve subjects above described and has a feature that a semiconductor optical device provides a current blocking layer without any pn-junction.

### SUMMARY OF THE INVENTION

One aspect of the present invention relates to a semiconductor optical device that provides a ridge waveguide structure and a current blocking layer formed so as to bury the ridge waveguide structure. The current blocking layer of the invention may be made of un-doped group III-V compound semiconductor material, one of un-doped GaInP and un-doped AlGaInP grown at a relatively low temperature. Because these un-doped semiconductor material grown at a low temperature, between 500° C. and 600° C., shows substantially semi-insulating characteristic with the resistance thereof greater than 10⁵ Ω·cm, the optical device may provide the current blocking layer without any pn-junction, impurity doped layer nor materials except for the semiconductor, whereby the device may operate in higher modulation frequencies and enhance the reliability thereof.

Another aspect of the invention relates to a method to form the semiconductor optical device. The method comprises steps of: (a) sequentially growing semiconductor layers on a GaAs substrate with a first conduction type, semiconductor layers including a lower cladding layer, an active region and an upper cladding layer; (b) forming a ridge structure including the upper cladding layer by etching; and (c) growing an un-doped current blocking layer at a relatively low temperature from 500 to 600° C. The un-doped current blocking layer may be one of un-doped GaInP and un-doped AlGaInP.

The active region may include a double quantum well structure comprising two well layers made of un-doped GaInNAs and a GaAs barrier layer put between the GaInNAs well layers. Because the GaInNAs layer is so sensitive to the thermal stress, the low temperature growth for the current blocking layer of the invention may escape the well layers from being affected by the thermal stress, whereby the device may show a preferable reliability.

### BRIEF DESCRIPTION OF DRAWINGS

FIG. 1 shows a cross section of a semiconductor optical device according to the first embodiment of the invention;

FIGS. 2A and 2B show the resistance against the applied voltage of specimens including an un-doped GaInP grown at 500° C. and 550° C., respectively;

FIG. 3 calculates the optical output with respect to the supplied current, which is often called as the I-L characteristic, based on the structure shown in FIG. 1;

FIGS. 4A to 4F are cross sections at respective process steps for manufacturing the semiconductor optical device;

FIG. 5 shows a cross section of another semiconductor optical device according to the second embodiment of the invention; and

FIG. 6 shows a cross section of still another semiconductor optical device according to the third embodiment of the invention.

### DESCRIPTION OF PREFERRED EMBODIMENTS

Next, preferred embodiments of the present invention will be described as referring to accompanying drawings. In the description of the drawings, the same symbols or numerals will refer to the same elements without overlapping explanations.

### First Embodiment

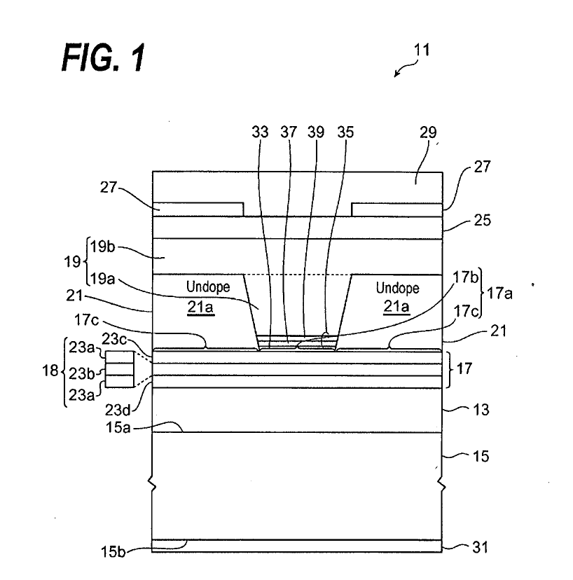

FIG. 1 is a cross section showing a semiconductor optical device according to one embodiment of the present invention. The semiconductor optical device 11 includes; a lower cladding layer 13 with the first conduction type on the primary surface 15a of the GaAs substrate 15; the active region 17, which is formed on the lower cladding layer 13, includes the first and second regions, 17b and 17c, respectively, in the primary surface 17a thereof; the upper cladding layer 19 with the second conduction type that includes a first portion 19a constituting the ridge waveguide structure on the first region 17b; and the current blocking layer 21, which is provided on the second region 17c of the active region 17 and includes a semiconductor layer 21a made of un-doped group III-V compound semiconductor material with high resistance.

In the semiconductor device 11, the current blocking layer 21 buries the first portion 19a, the ridge waveguide structure, of the upper cladding layer 19. Because the un-doped layer 21a constitutes the current blocking layer 21, the resistance thereof may be several digits greater than that of the first portion 19a of the upper cladding layer 19. Thus, this arrangement of the current blocking layer 21 may confine the current within the ridge waveguide structure. The current blocking layer 21 blocks the current by the intrinsic resistance thereof without any pn-junction, which may reduce the parasitic capacitance that conventionally degrades the performance of the high-speed operation of the device.

The band gap energy of the current blocking layer 21 is preferably greater than that of the upper cladding layer 19. A combination of the AlGaInP with the GaInP is a preferable example for the un-doped semiconductor layer 21a and the upper cladding layer 19, respectively. This combination of semiconductor materials confines the current within the ridge waveguide structure more efficiently compared to a configuration where the current blocking layer and the upper cladding layer are made of the same semiconductor material but the conduction types thereof are different from each other, because the present combination forms a hetero-barrier between the current blocking layer 21 and the upper cladding layer 19. Moreover, the effective refractive index of the center region including the ridge waveguide structure becomes greater than that of the side region including the un-doped layer 21a, which realizes the index-guided mode of the light propagation, where the light is efficiently confined within the active layer to enhance the stimulated emission, thereby increasing the emission efficiency of the device.

The active region 17 of the device 11 may include the double quantum well structure for the active layer 18 as shown in FIG. 1. However, the active layer 18 is not restricted to this arrangement. For instance, the bulk structure, the single quantum well structure, or the multiple quantum well structure may be applicable to the active layer 18. The active layer 18, as typically shown in FIG. 1, may include two well layers 23a and single barrier layer 23b put between the well layers 23a. In a modification, the active region 17 may include the upper and lower optical confinement layers, 23c and 23d, provided so as to put the active layer 18 therebetween.

These upper and lower optical confinement layers, 23c and 23d, may have the band gap energy intermediate between that of the cladding layers, 13 or 19, and the quantum well layer 23a, where electrons and holes supplied from each cladding layer, 13 or 19, may be effectively injected into the quantum well layer 23a without being blocked by the optical confinement layers, 23c and 23d. Further, each optical confinement layer, 23d or 23c, may have the refractive index intermediate between that of the lower or the upper cladding layer, 13 or 19, and the quantum well layer 23a, in which the both cladding layers, 13 and 19, may effectively confine the light generated in the active layer 18 within the active layer 18 and the optical confinement layers, 23c and 23d. Thus, the optical confinement layers, 23c and 23d, may confine the light within the active layer 18 without degrading the carrier injection into the active layer 18, which enhances not only the emission characteristic of the device 11 but also the temperature characteristic thereof.

Exemplary conditions of layers and regions of the device 11 are listed in the following:

TABLE 1
Conditions of each layer

| Layer/Region | Material | thickness |
|---|---|---|
| Substrate 15 | n-type GaAs | 100 μm |
| lower cladding layer 13 | n-type GaInP | 1.5 μm |
| active region 17 | | |
| well layer 23a | un-doped GaInNAs | 7 nm |
| barrier layer 23b | un-doped GaAs | 8 nm |
| upper optical confinement layer 23c | un-doped GaAs | 140 nm |
| lower optical confinement layer 23d | un-doped GaAs | 140 nm |
| upper cladding layer 19 | | |
| first portion 19a | p-type GaInP | 400 nm |
| second portion 19b | p-type GaInP | 1.1 μm |
| current blocking layer 21 | un-doped GaInP | 430 nm |

This semiconductor optical device, which shows a function of the semiconductor laser diode, enables to emit light with wavelengths greater than 1 μm, specifically between 1 and 1.6 μm, by the quantum well layers 23a made of GaInNAs. The device 11 provides the un-doped GaInP current blocking layers 21 in both sides of the ridge waveguide structure. The un-doped GaInP shows substantially semi-insulating characteristic, accordingly, the arrangement shown may confine the current within the ridge waveguide structure. The composition of the GaInP in the un-doped current blocking layer is so determined to match the lattice constant thereof with that of the GaAs substrate, whereby the GaInP may be grown on the GaAs substrate with quite good quality.

The cladding layers, 13 and 19, may be made of AlGaAs, GaInAsP or AlGaInP instead of GaInP. The optical confinement layers, 23c and 23d, may be made of AlGaAs, AlGaInP, GaInAsP, or GaInP, instead of GaAs. These materials may be matched in a lattice constant thereof with that of the GaAs substrate 15, which enables to grow layers epitaxially on the GaAs substrate 15 with good crystal quality.

Moreover, the quantum well layer 23a, not restricted to GaInNAs, may be made of other group III-V compound semiconductor materials containing gallium (Ga), nitrogen (N), and arsenic (As), specifically, GaNAs, GaInNAsP, GaInNAsSb, or GaInNAsSbP may be applicable to the quantum well layer 23a. Even a laser diode selecting such materials for the well layer may emit light with wavelengths greater than 1 μm.

The upper cladding layer 19 further provides the second portion 19b formed on the current blocking layer 21 in addition to the first portion 19a. The second portion 19b may be made of p-type GaInP with a thickness of about 1.1 μm and may be lattice-matched to the GaAs substrate 15. The device 11 may lower the ridge waveguide structure of the first portion 19a because the sum of the first and second portions, 19a and 19b, may contribute the optical confinement, which shortens the etching time for forming the ridge waveguide structure, as a result, enhances the reproducibility and the uniformity of the width of the ridge waveguide. Moreover, the lowered ridge waveguide structure may shorten the process time to grow the current blocking layer 21, which escapes the process from several disadvantages such as (1) the deposition of poly crystals on the mask to protect the ridge waveguide structure and (2) the anomalous growth of the current blocking layer 21 at the boundary between the ridge 19a and the current blocking layer 21.

On the second portion 19b is provided with the contact layer 25, and on the contact layer 25 is provided with an insulating layer 27 so as to partly cover the contact layer 25. Further, on the contact layer 25 and the insulating layer 27 are provided with the first electrode 29, for instance, an anode electrode of the device, such that the electrode 29 comes in contact with the contact layer 25 through the opening in the insulating layer 27. While, on the back surface 15b of the GaAs substrate 15 is provided with another electrode 31, for instance, a cathode electrode. In the embodiment shown in FIG. 1, the contact layer 25 is the p-type GaAs with a thickness of 0.2 μm and the insulating layer 27 may be made of dielectric material such as SiN or SiO₂. The insulating layer 27 provides the opening through which the electrode 29 comes in contact with the contact layer 25, and this opening aligns with the first portion 19a of the upper cladding layer 19.

The optical device 11 provides the current blocking layer 21 made of un-doped group III-V compound semiconductor material 21a, which shows the quite high resistance. Accordingly, the current blocking layer 21 can block, without any additional layers to form the pn-junction, the current flowing outside the ridge waveguide structure 19a, which makes it possible to remove the planar region of the upper cladding layer between the current blocking layer and the active region, which is inevitable in the conventional device with the ridge waveguide structure. To remove the planar region with the second conduction type may automatically reduce the leak current due to the horizontal diffusion of the carriers in this planar layer. Thus, the arrangement of the present invention may solve the disadvantages due to the leak current accompanied with the conventional structure shown in the aforementioned prior art, such as the increase of the laser threshold current and the reduction of the emission efficiency.

Moreover, the un-doped current blocking layer 21a with the high resistance may reduce the parasitic capacitance compared to the is conventional current blocking structure with the pn-junction, which enables the device to operate in higher modulation frequencies.

Next, the un-doped III-V semiconductor material for the current blocking layer 21 will be described in detail. The un-doped semiconductor material may be GaInP or AlGaInP that is formed by the following process, shows the high resistance, and has wider band gap energy compared to those applied in the conventional device. Accordingly, these materials may enlarges the hetero-barrier between the cladding layer 19 and the current blocking layer 21, which reduces the leaking of the carriers from the cladding layer 19 to the current blocking layer 21 and confines the carrier into the ridge waveguide structure. The un-doped layer 21 may have the resistance greater than 10⁵ Ω·cm, which is at least six digits greater than the resistance of the ridge waveguide region 19a, to confine the carriers within the ridge waveguide structure 19a effectively because of this huge difference of the resistance.

The GaInP with the high resistance may be obtained from the low temperature epitaxial growth below 600° C. Such low temperature growth may induce deep levels within the energy band gap of the grown material. These deep levels become a trapping center for both the electrons and the holes. Accordingly, the grown material may show the high resistance.

The GaInP formed by the low temperature growth was evaluated in the resistance thereof as follows: a specimen having a p-i-n junction comprising (a) an n-type GaInP with a thickness of 0.5 μm and doped with silicon (Si) by 1×10¹⁷ cm⁻³, (b) an un-doped GaInP with a thickness of 1.5 μm and (c) a p-type GaInP with a thickness of 0.5 μm and doped with zinc (Zn) by 7×10¹⁷ cm⁻³; and a contact layer of a p-type GaAs with a thickness of 0.2 μm doped with Zn by 1×10¹⁹ cm⁻³ was prepared. These layers were provided on an n-type GaAs substrate. The n-type GaInP behaved as the electron supplying layer, while, the p-type GaInP behaved as the hole supplying layer to the un-doped GaInP layer put between these doped layers. The growth of these layers was carried out by the organic metal vapor phase epitaxy (OMVPE) technique. The grown temperature for the un-doped GaInP was between 500 and 600° C.

The p-i-n junction region of the specimen was formed in the mesa shape with a diameter of about 200 μm, and electrodes were provided on the contact layer and the back surface of the GaAs substrate after the formation of the mesa. The I-V characteristic of thus prepared specimen was measured as applying the forward bias to the p-i-n junction, and the resistance of the specimen was calculated from this I-V characteristic.

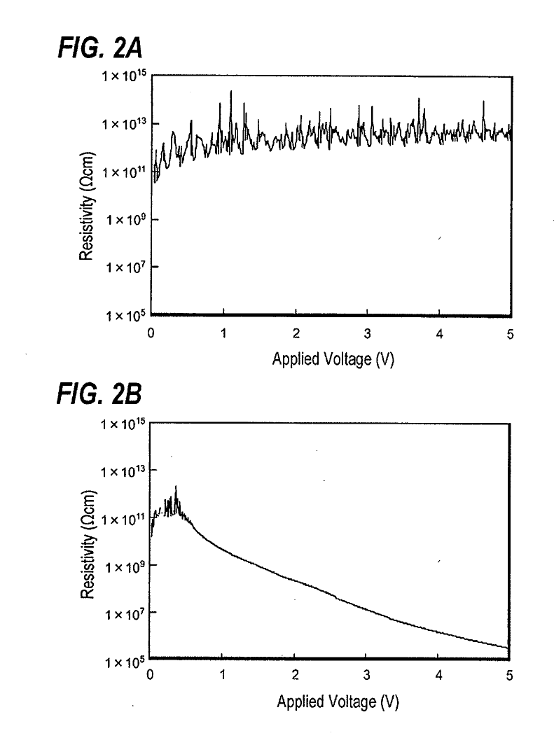

FIG. 2A shows a behavior of the resistance against the applied bias for the specimen grown at 500° C., while, FIG. 2B shows a behavior of the resistance for the specimen grown at 550° C. It is understood that quite a high resistance greater than 10⁵ Ω·cm can be obtained for both specimens at biases smaller than 5 V, which is a normal operating condition of the laser diode. Moreover, the first specimen shown in FIG. 2A, which was grown at 500° C., shows a higher resistance compared to the other specimen grown at 550° C.

Thus, FIGS. 2A and 2B indicate that, the un-doped GaInP grown at relatively low temperatures contains a great number of the deep levels behaving as the trapping center for both electrons and holes, and shows the quite high resistance for both carriers. This is because, if the deep levels of the un-doped GaInP can capture only one of carriers, a leak current due to the other carriers not captured by the deep levels becomes substantial and the high resistance such as shown in FIGS. 2A and 2B would be unobtainable.

The un-doped GaInP grown at low temperatures was verified to behave as a layer with high resistance for both electrons and holes. Because the resistance of the ridge waveguide region 19a is about 0.2 Ω·cm, the current blocking layer 21 made of un-doped GaInP shows the resistance at least six digits greater than that of the ridge waveguide region 19a. Accordingly, the un-doped GaInP grown at the low temperature may be applicable to the current blocking layer.

A semiconductor laser based on the InP substrate often provides the current blocking layer with the high resistance made of InP doped with iron (Fe). The iron (Fe) doped within the InP behaves as the trapping centers for the electron, whereby the Fe-doped InP is applicable to a high resistive layer for the electrons. However, because the Fe-doped InP does not capture the holes, the Fe-doped InP is unable to operate as the current blocking layer for the p-type cladding layer where the hole is the majority carrier. The un-doped material, such as GaInP grown at the low temperature, may show the high resistance for both the electron and the hole, accordingly, such material becomes applicable as the current blocking layer for the p-type and the n-type cladding layers, which enhances the flexibility as the current blocking layer. In addition, the un-doped material needs no impurity such as Fe and no additional apparatus for doping it, so that it may be easily grown compared to the doped materials such as Fe-doped InP.

When the impurities are doped in order to obtain a material with the high resistance, such as Fe-doped InP, the inter-diffusion of the impurities often occurs during the growing process. For example, it is well known that the iron (Fe) contained in the InP current blocking layer easily inter-diffuses with the zinc (Zn) contained in the cladding layer as the p-type dopant. The inter-diffusion of impurities causes the decrease of the resistance of the current blocking layer. The present current blocking layer made of un-doped material may escape from such subject because of its inherently un-doped characteristic.

The optical device shown in FIG. 1 further provides a waveguiding layer 33 on the first portion 17b of the active region 17. The refractive index of this waveguiding layer 33 is greater than that of the current blocking layer 21. Because the effective refractive index in a portion including the ridge waveguide structure 19a becomes greater than that in portions outside the ridge structure 19a due to the difference in the refractive index of the waveguiding layer 33 and that of the current blocking layer 21, the index-guided mode for the light generated in the active region 17 may be realized. In the index-guided mode, the light may be effectively confined in the active region; accordingly, the efficiency of the stimulated emission may be enhanced to improve the lasing characteristic.

Other conditions of the optical device 11 in addition to those listed in Table I are listed below in Table 2:

TABLE 2
Additional conditions of the optical device

| Layer/Region | Material | thickness |
|---|---|---|
| contact layer 25 | p-type GaAs | 0.2 μm |
| Insulating layer 27 | Dielectric material | |
| waveguiding layer 33 | un-doped GaInAsP | 30 nm |

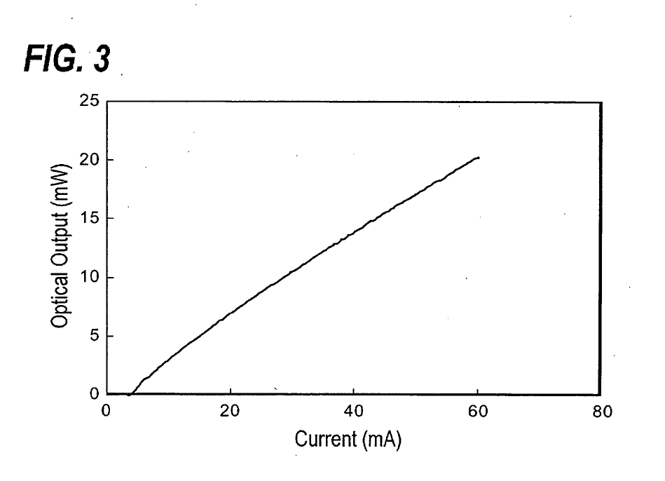

FIG. 3 shows an I-L (current to light) characteristic calculated based on the structure shown in FIG. 1. The calculation assumes that the device has the optical cavity, a length of which is 300 μm and both facets defining the optical cavity are un-coated, and the resistance of the current blocking layer 21 refers to the result shown in FIG. 2A, which corresponds to the specimen grown at 500° C. The I-L characteristic shows the relatively small threshold current and the good linearity, which demonstrates that the un-doped GaInP current blocking layer grown at the low temperature, may effectively confine the current within the ridge waveguide structure.

The waveguiding layer 33, not restricted to GaInAsP exemplary illustrated above, may be AlGaAs, GaAs, AlGaInP or GaInP. The cladding layer is also not restricted to GaInP, other materials such as AlGaAs, GaInAsP, and AlGaInP may be applicable. Moreover, the optical confinement layer may be AlGaAs, AlGaInP, GaInAsP, and GaInP in stead of GaAs described above. The current blocking layer may be AlGaInP substituting for GaInP.

The device 11 may further provide the grating structure 35 for the distributed feedback laser, where the grating structure 35 includes a grating layer 39 with a refractive index different from that of the upper cladding layer 19 so as to form the diffraction grating. The device 11 may further provide the etching-stop layer 37 on the waveguiding layer 33. The etching-stop layer 37 and the grating layer 39 for the grating structure 35 are provided on the waveguiding layer 33 such that the etching-stop layer 37 is put between the waveguiding layer 33 and the grating layer 39. Exemplary conditions for these layers are shown in Table 3:

TABLE 3
Conditions of additional layers

| Layer/Region | Material | thickness |
|---|---|---|
| waveguiding layer 33 | un-doped GaInAsP | 30 nm |
| etching-stop layer 37 | p-type GaInP | 20 nm |
| grating layer 39 | p-type GaAs | 20 nm |

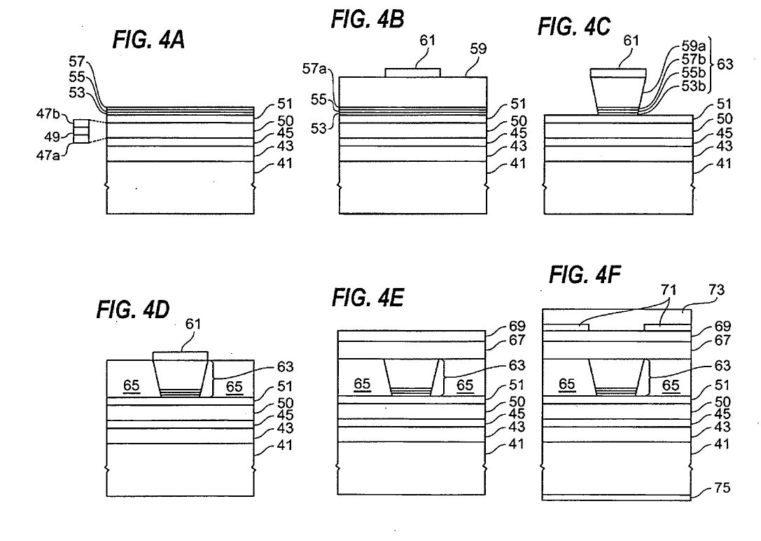

Next, a method for producing the optical device 11 shown in FIG. 1 will be described as referring to FIG. 4. The process may use the OMVPE technique for the growth of respective semiconductor layers. First, an n-type GaAs substrate 41 is prepared. The first epitaxial growth sequentially stacks, on the n-type GaAs substrate 41, an n-type GaInP lower cladding layer 43, an un-doped GaAs lower optical confinement layer 45, an un-doped GaInNAs quantum well layer 47a, an un-doped GaAs barrier layer 49, an un-doped GaInNAs another quantum well layer 47b, an un-doped GaAs upper optical confinement layer 51, an un-doped GaInAsP waveguiding layer 53, a p-type GaInP etching-stop layer 55, and a p-type GaAs grating layer 57. The un-doped GaInNAs quantum well layer 47a, the un-doped GaAs barrier layer 49 and the un-doped GaInNAs quantum well layer 47b constitute the double quantum well structure 50.

Next, the process provides a resist mask on the p-type GaAs grating layer 57. This mask includes a striped pattern iterating the covered portion and the exposed portion alternately with a period of A that corresponds to the period of the grating structure. The process may use the holographic exposure technique or the electron beam lithography to form the periodic mask pattern. Subsequently to the formation of this mask, the p-type GaAs grating layer 57 may be wet-etched with an etchant including phosphoric acid to obtain the grating layer 57a which is made of the p-type GaAs and provides the diffraction grating with the period Λ in the surface thereof. The etchant containing the phosphoric acid is substantially unable to etch the GaInP etching-stop layer. Accordingly, when the GaInP etching-stop layer is exposed, the wet-etching automatically stops. Thus, the p-type GaInP layer 55 behaves as an etching-stop layer. Even when the etching rate varies in each etching batch, or the rate varies within a wafer on which the device is to be formed, the etching of the grating layer 57 is able to be stopped at this etching-stop layer 55, which enhances not only the uniformity of the grating layer 57a but also improves its reproducibility and its uniformity within the wafer. After the wet-etching, the second growth forms the upper cladding layer 59 made of the p-type GaInP.

FIG. 4B illustrates a step subsequent to the growth of the upper cladding layer 59, where a mask 61 made of dielectric material is formed on the p-type GaInP cladding layer 59. The dielectric material may be silicon nitride (SiN) or silicon oxide (SiO₂). An etching forms the ridge structure 63, which is shown in FIG. 4C and includes the GaInAsP waveguiding layer 53b, the p-type GaInP etching-stop layer 55b, the p-type GaAs grating layer 57b, and the p-type GaInP upper cladding layer 59a. FIG. 4C illustrate the ridge structure with a reverse trapezoid, however, the cross section of the ridge structure 63 can be changed by choosing the surface direction of the wafer, the direction of the mask 61, the type of the etchant, and combinations of these conditions. A hydrochloric acid is applicable to etch the p-type GaInP cladding layer 59 and the p-type GaInP etching-stop layer 55 to form the ridge structure 63, while, the phosphoric acid is available to etch the p-type GaAs grating layer 57a and the GaInAsP waveguiding layer 53.

The third growth forms the un-doped current blocking layer 65 with the same mask 61 to form the ridge structure 63. The third growth may be carried out in low temperatures, where only on the exposed portion of the optical confinement layer 51 is formed with the un-doped GaInP current blocking layer without grown on the mask 61 so as to bury the ridge structure 63.

Because the third growth is carried out at low temperatures, for instance, from 500 to 600° C., the process does not degrade the crystal quality of the active region 50. In particular, the ternary or quaternary compound containing gallium (Ga), arsenic (As) and nitrogen (N), such as GaInNAs in the present active region, is sensitive to thermal stress, accordingly, the current blocking layer grown at a low temperature has a great advantage. After removing the mask 61, the forth growth forms the p-type GaInP upper cladding layer 67 and the p-type GaAs contact layer 69 on the ridge structure 63 and on the current blocking layer 65, which is illustrated in FIG. 4E.

Finally, forming a dielectric film 71 made of silicon nitride (SiN) on the whole surface so as to protect the processed layers, the process polishes the back surface of the n-type GaAs substrate to a thickness thereof about 100 μm. To form the anode and cathode electrodes, 73 and 75, completes the laser diode with a type of the buried ridge structure.

The optical device 11 according to the present embodiment provides the second portion 67 as the upper cladding layer in addition to the first portion 59a that constitutes the ridge structure. This arrangement makes it possible to lower the ridge structure because, in this structure, only the lower part of the upper cladding layer is necessary to be processed into the ridge structure in order to confine current. The lowered ridge structure enables to shorten the process time to grow the current blocking layer 65 to bury the ridge structure 63 shown in FIG. 4D as well as the etching time to form the ridge structure 63. Consequently, various subjects may be solved, for instance, the deposition of poly crystals on the mask 61 and/or the anomalous growth of the current blocking layer at the boundary between the ridge 63 and the current blocking layer 65.

The manufacturing process is thus described for the device with the grating. However, other devices without the grating layer such as shown in FIG. 1 may be obtained through a similar process except for the step to form the grating layer 57b. Assuming the arrangement where the p-type GaInP forms the ridge structure 19a, while, the un-doped GaAs forms the upper optical confinement layer 23c, the wet-etching using the hydrochloric acid substantially stops when the underlying GaAs optical confinement layer 23c is exposed because the GaAs is substantially unable to be etched by the hydrochloric acid. That is, the GaAs optical confinement layer 23c operates as the etching-stop layer in this case.

Therefore, even the etching rate for the GaInP upper cladding layer varies within the wafer or in batch to batch, the etching of the upper cladding layer 19 substantially securely stops at the underlying GaAs optical confinement layer 23c, which enhances the dimensional uniformity and reproducibility of the ridge structure 19a. To secure the uniformity of the ridge structure 19a and the reproducibility of the etching process, it is conventionally inevitable to provide an etching-stop layer between the upper cladding layer 19 and the active region 17 to realize the selective etching function. However, the etching-stop layer increases the intrinsic resistance of the device due to the hetero-barrier formed at the interface between this etching-stop layer and the adjacent layers, which is inevitably followed by a greater heat generation within the device and would degrade the device performance and the reliability.

On the other hand, the present layer combination, where the upper optical confinement layer 23c behaves as the etching-stop layer, may omit the specific layer to stop the wet-etching. Thus, the present device may be released from various disadvantages derived from the etching-stop layer. The embodiment described above, where the optical confinement layer shows the function of the etching-stop layer, combines the p-type GaInP upper cladding layer with the un-doped GaAs optical confinement layer 23c for the hydrochloric acid. However, other combinations of the semiconductor layers and the etchant may be applicable as long as the underlying semiconductor layer has the function of the etch-stopper for the specific etchant.

### Second Embodiment

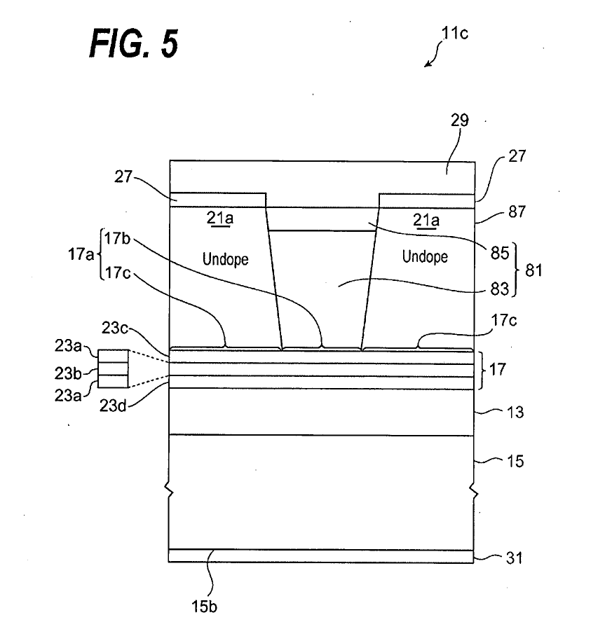

FIG. 5 illustrates a semiconductor optical device according to the second embodiment of the present invention. The optical device 11c shown in FIG. 5 provides, similar to the device of the first embodiment, the lower cladding layer 13 with the first conduction type and the active region 17 on the lower cladding layer 13. These region 17 and layer 13 are provided on the GaAs substrate 15 with the first conduction type.

On the active region 17 is provided with the ridge waveguide structure 81 that includes, in addition to the upper cladding layer 83 with the second conduction type, the contact layer 85 with the second conduction type. That is, although the first embodiment provides the contact layer 25 spread in a whole region of the device, namely, on the ridge waveguide structure 19a and the current blocking layer 21a. While, the optical device according to the present embodiment comprises the contact layer 85 localized within the ridge structure 81. The current blocking layer 87, which positions in both sides of the ridge structure 81 and on the second region 17c of the active region 17, buries the ridge structure 81. This current blocking layer 87 includes, similar to the first embodiment, the layer 21a made of un-doped III-V compound semiconductor material. Because the ridge structure 81 includes the contact layer 85 in the top thereof, whereby the process enables to omit one step of the crystal growth, this not only simplifies the process step but reduces the cost thereof and relaxes the thermal stress to be applied to the active region 17. Thus, even when the active region comprise ternary or quaternary compound material that contains Ga, As and N, which is sensitive to the thermal stress as mentioned previously, such active region 17 can show the superior characteristic in the present embodiment.

The device 11c also provides the un-doped current blocking layer 87 whose resistance is at least several digits greater than that of the ridge structure 81; accordingly, the current blocking layer 87 effectively confines the current in the ridge structure 81. Moreover, the un-doped current blocking layer 87 may decrease the parasitic capacitance compared to the conventional current blocking structure with the pn-junction formed by the doped semiconductors.

The un-doped material of the current blocking layer 87 preferably has the band gap energy greater than that of the upper cladding layer 83 to effectively confine the current within the ridge structure 81. In this combination of the cladding layer 83 and the un-doped current blocking layer 87, the refractive index of the former layer 83 becomes greater than that of the latter layer 87, in other words, the effective refractive index of the center region including the ridge structure 81 becomes higher than that of the side region including the current blocking layer 87, which realize the index-guided structure that can efficiently confine the light in the active region; accordingly, this can enhance the stimulated emission and the laser oscillation characteristic.

On the contact layer 85 with the second conduction type and on the un-doped current blocking layer 87 is provided with the insulating layer 27. Moreover, on the insulating layer 27 and on the contact layer 85 is provided with the first electrode 29, while, on the back surface 15b of the GaAs substrate 15 with the first conduction type is provided with the second electrode 31.

The current blocking layer 87 of this embodiment may be, similar to that of the first embodiment, one of GaInP and AlGaInP grown at relatively low temperatures below 600° C. and preferably over 500° C. The GaInP or AlGaInP grown at the low temperature shows the semi-insulating characteristic. As described previously in the present application, the un-doped layer preferably shows the resistance greater than 10⁵ Ω·cm, which is at least six digits greater than that of the ridge structure 81 and effectively prevents the current from flowing in the current blocking layer 87 to confine it in the ridge structure 81.

### Third Embodiment

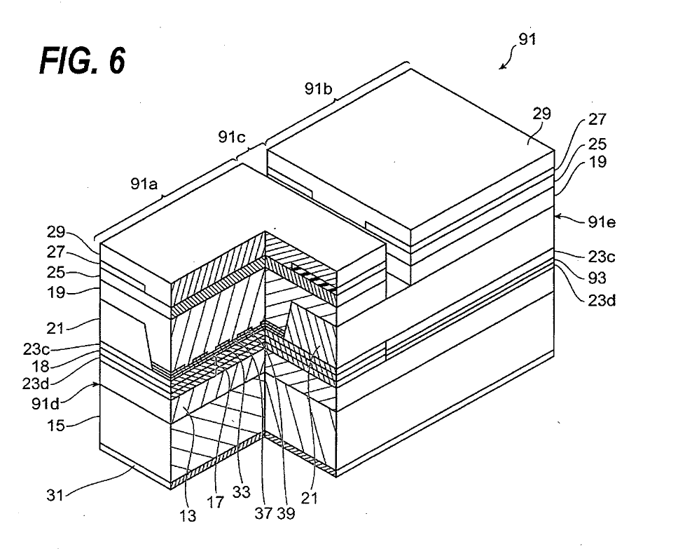

FIG. 6 illustrates still another semiconductor optical device according to the third embodiment of the invention. The optical device 91 integrates a distributed feedback laser diode (hereafter denoted as DFB-LD) 91a with an optical modulator with a type of an electro-absorption (hereafter denoted as EA-modulator) 91b. The DFB-LD 91a provides the layer arrangement described previously in this specification and those materials listed in Tables may be applicable to each semiconductor layer within the device 91a.

The device 91 provides a butt-jointing structure that optically couples the DFB-LD 91a with the EA-modulator 91b. The EA-modulator 91b includes an optical absorption layer 93 which contrasts with the active layer 18 in the DFB-LD 91a and excludes the grating layer 39 and the etching-stop layer 37 underlying the grating layer 39. Except for the arrangement above, the EA-modulator 91b has layer structures and materials applied thereto substantially same as those of the DFB-LD 91a.

The device 91 further provides an isolating region 91c between the DFB-LD 91a and the EA-modulator 91b to reduce the leak current between them, which makes the device 91 stable in the operation thereof. The isolating region 91c, where the contact layer 25 and the upper cladding layer 19 in a portion or a whole there of are removed, which may increase the resistance between the devices.

On the facet 91d of the DFB-LD 91a is coated with a high-reflectivity film to increase the optical output power, while, the facet 91e of the EA-modulator 91b is coated with the anti-reflectivity film to prevent the unstable operation due to the optical feedback from the facet 91e. The active layer 18 of the DFB-LD 91a and the optical absorption layer 93 of the EA-modulator 91b both provides the multiple quantum well (MQW) made of GaInNAs and GaAs. But specific structure of these MQW structures is distinguishable, for example, the composition and the thickness of each well layer, or the number of layers of respective well layers are optimized in each device.

The GaInNAs in the quantum well layer of the optical absorption layer 93 in the EA-modulator 91b preferably has band gap energy greater than that of the active layer 18 at no bias condition to suppress the optical absorption of the light generated in the active layer 18 of the DFB-LD 91a. The followings are exemplary conditions of the device 91:

TABLE 4
Conditions in composite device

| | material | thickness |
|---|---|---|
| DFB-LD 91a | | |
| active layer 18 | | |
| well layer | un-doped Ga_{0.65}In_{0.35}N_{0.006}As_{0.994} | 7 nm |
| barrier layer | un-doped GaAs | 8 nm |
| number of wells | 2 | |
| EA-modulator 91b | | |
| optical absorption | | |
| layer 93 | | |
| well layer | un-doped Ga_{0.75}In_{0.25}N_{0.01}As_{0.99} | 7 nm |
| barrier layer | un-doped GaAs | 8 nm |
| number of wells | 6 | |

The EA-modulator described in the table 4 gives a practical extinction ratio of the light propagated therethrough at a device length of 300 μm under a bias condition of 5 volts.

The device disclosed in the aforementioned prior art that integrates the laser diode with the EA-modulator and has the n-type current blocking layer to bury the ridge waveguide structure is necessary to remove all of the current blocking layer in addition to the contact layer and the upper cladding layer in order to increase the resistance in the isolating region, because the contact layer, the upper cladding layer, and the current blocking layer show relatively small resistance. Moreover, one of the upper cladding layers puts the current blocking layer and the waveguiding layer therebetween. Therefore, these layers are impossible to be removed at a time and necessary to change etchant suitable for each layer and to etch individually, which makes the process complex, raises the process cost and lowers the yield.

Moreover, the isolating region excludes the current blocking layer and the upper cladding layer in the conventional device. Accordingly, the discontinuity of the waveguide function in the isolating region increases, which increases the optical reflection thereat and degrades the optical coupling between two devices. The light reflected at the boundary returns the DFB-LD and makes the operation of the DFB-LD unstable. The loss of the optical coupling at the boundary decreases the optical output from the EA-modulator.

On the other hand, the device according to the invention provides the un-doped current blocking layer 21 that intrinsically shows the high resistance, accordingly, to remove only the upper cladding layer 19 and the contact layer 25 forms the isolating region with high resistance. Moreover, in the upper cladding layer 19 and in the contact layer 25 are provided with no other layer, which may simplify the process to form the isolating region compared to those for the conventional device. The isolating region leaves the current blocking layer with the high resistance, which may alleviate the discontinuity of the optical waveguide. Thus, the reflection at the isolating region may be reduced to suppress the degradation in the performance of the device.

The DFB-LD 91a of the present device provides the structure of the first embodiment; however, the structure according to the second embodiment may be applicable to the present DFB-LD 91a. Persons skilled in this field would easily adjust the structure of the EA-modulator 91b following the change of the structure in the DFB-LD 91a.

While the present invention has been described with reference to the specific embodiments thereof, it should be understood by those skilled in the art that various changes may be made and equivalents may be substituted without departing from the true spirit and scope of the invention. In addition, many modifications may be made to adapt a particular situation, material, composition of matter, process, process step or steps, to the objective, spirit and scope of the present invention. Although the embodiments exemplarily describe the semiconductor laser diode, the invention is not restricted to such device. The present invention may be modified so as to fit to other optical devices, such as light-emitting diode and semiconductor optical amplifier. All such modifications are intended to be within the scope of the claims appended hereto.

I claim:

1. A semiconductor optical device with a ridge waveguide structure, comprising:
a GaAs substrate with a first conduction type;
a lower cladding layer with the first conduction type provided on the GaAs substrate;
an active region with a primary surface including a first portion and a second portion, the active region being provided on the lower cladding layer with the first conduction type and including an active layer;
an upper cladding layer with a second conduction type different from the first conduction type, the upper cladding layer including a first portion with the ridge structure provided on the first portion of the active region; and
a current blocking layer made of un-doped group III-V compound semiconductor material, the current blocking layer being provided on the second portion of the active region.

2. The semiconductor optical device according to claim 1,
wherein the un-doped group III-V compound semiconductor material is one of GaInP and AlGaInP.

3. The semiconductor optical device according to claim 1,
wherein the un-doped group III-V compound semiconductor material has resistance greater than 10⁵ Ω·cm.

4. The semiconductor optical device according to claim 1,
wherein the un-doped group III-V compound semiconductor material has band gap energy greater than band gap energy of the first portion of the upper cladding layer with the second conduction type.

5. The semiconductor optical device according to claim 1,
wherein the upper cladding layer further provides a second portion with second conduction type provided on the first portion of the upper cladding layer and on the current blocking layer.

6. The semiconductor optical device according to claim 5,
further comprising a contact layer with the second conduction type, the contact layer being provided on the second portion of the upper cladding layer with second conduction type.

7. The semiconductor optical device according to claim 1,
further comprising a contact layer with the second conduction type, the contact layer being provided on the first portion of the upper cladding layer with the second conduction type,
wherein the first portion of the upper cladding layer and the contact layer forms the ridge structure.

8. The semiconductor optical device according to claim 1,
further comprising a grating layer provided between the active region and the first portion of the upper cladding layer, the grating layer including a diffraction grating on a surface thereof,
wherein the grating layer and the first portion of the upper cladding layer forms the ridge structure.

9. The semiconductor optical device according to claim 1,
further comprising a lower optical confinement layer provided between the active layer and the lower cladding layer, and an upper optical confinement layer provided between the active layer and the upper cladding layer.

10. The semiconductor optical device according to claim 9,
further comprising a grating layer provided between the upper optical confinement layer and the first portion of the upper cladding layer with the second conduction type,
wherein the grating layer and the first portion of the upper cladding layer forms the ridge structure.

11. The semiconductor optical device according to claim 1,
wherein the active region includes a double quantum well structure comprising two well layers made of GaInNAs and a barrier layer made of GaAs put between the well layers.

12. A method of manufacturing a semiconductor optical device, comprising steps of:
sequentially growing a lower cladding layer with a first conduction type, an active region, and an upper cladding layer with a second conduction type different from the first conduction type on a GaAs substrate with a first conduction type;
forming a ridge structure by etching the upper cladding layer; and
growing a current blocking layer made of one of un-doped GaInP and un-doped AlGaInP at a temperature from 500° C. to 600° C. so as to bury the ridge structure.

13. The method according to claim 12,
wherein the sequential growth further includes a growth of a grating layer after the growth of the active region before the growth of the upper cladding layer, and
wherein the formation of the ridge structure includes the etching of the grating layer after the etching of the upper cladding layer.

14. The method according to claim 12,
further comprising steps of:
growing an additional upper cladding layer with the second conduction type on the ridge structure and on the current blocking layer after the growth of the current blocking layer, and
growing a contact layer with the second conduction type on the additional upper cladding layer.

15. The method according to claim 12,
wherein the sequential growth of semiconductor layers includes a growth of a contact layer with the second conduction type on the upper cladding layer, and
wherein the formation of the ridge structure includes the etching of the contact layer provided on the upper cladding layer, the ridge structure including the upper cladding layer and the contact layer.
